(19) United States
(12) Patent Application Publication
(10) Pub. No.: US 2005/0227417 A1
(43) Pub. Date: Oct. 13, 2005

(54) Packaging assembly utilizing flip chip and conductive plastic traces

(75) Inventors: Steven R. Shiffer, Pearl City, IL (US); John S. Patin JR., Freeport, IL (US); Brian L. Swartz, Freeport, IL (US)

Correspondence Address: Kris T. Fredrick;Honeywell International, Inc., 101 Columbia Rd., P.O. Box 2245, Morristown, NJ, 07962, US

(73) Assignee: Honeywell International Inc.

(21) Appl. No.: 10/819,819

(22) Filed: Apr. 6, 2004

(51) Int. Cl. H01L 29/06; H01L 29/08; H01L 39/00; H01L 21/44; H01L 21/48; H01L 21/50; H01L 23/48; H01L 23/52; H01L 29/40

(52) U.S. Cl. 438/125

(57) ABSTRACT

Packaging assembly methods and systems are disclosed herein. Initially, a plastic substrate can be provided. Thereafter, the plastic substrate can be configured as a conductive plastic trace assembly. One or more dies can be connected to the conductive plastic trace assembly, along with discrete metal components, so that the conductive plastic trace assembly functions as a combined printed circuit board and package structure including electronic circuitry. The die can be connected to the conductive plastic trace assembly utilizing a conductive adhesive. Alternatively, the die can be connected to the conductive plastic trace assembly by solder, ultrasonic bonding, and/or gold-to-gold bonding. The die is generally connected to the conductive plastic trace assembly utilizing FCOB techniques.

### TECHNICAL FIELD

Embodiments are generally related to integrated circuit manufacturing and assembly processes, including the packaging of electrical components. Embodiments also relate to Flip Chip and conductive plastic trace assembly methods and systems.

### BACKGROUND OF THE INVENTION

Most electronic packages, which include sensors connected to input/output devices thereof, utilize leadframes, a PCB, or combinations thereof. Such electronic packages generally require that conductors and/or insulators connect from a sensing element to the outside of the package for a customer to properly interface with the device. Leadframes provide customized configurations in which a designer can create many packages in order to meet a customer's overall need. Unfortunately, all of this customization must link in some electrical means to create a device. Common methods of connecting to leadframes including wire bonding and soldering techniques. Both of these connecting methods require that the leadframe be plated. Common plating material for wire bonding involves the use of gold, while tin is often utilized for soldering.

A number of complications are involved in the use of leadframes. For example, leadframes require cleaning following stamping and prior to plating in order to remove excessive oils and contaminates. Leadframes also function as a conductor and require an insulator to allow a usable electronic connection. Leadframes additionally require a significant capital investment to produce the conductor. The ability of a leadframe to be manipulated into a desired package configuration is very limited because the method of production chosen typically involves stamping. The simplest leadframe would be flat and straight. Any deviation from the simple design requires significant effort to ensure that angles and bends are precise for not only the package configuration, but also interface with the overmold process. It can thus be appreciated that the use of leadframes presents a number of assembly and manufacturing issues.

An alternative to leadframes is the PCB (Printed Circuit Board), which has become an economical means for producing circuitry utilizing copper foil, fiberglass, and resin to create the insulated conductor. This method maximizes the efficiency of the conductor when compared to the leadframe, because the conductor material requirement comes closer to meeting the electrical requirements required by the circuit. Yet, PCB issues include the cost of the board when the size becomes large. In addition, the conductor is merely flat.

Also, a requirement exists to provide interconnections to the PCB in order to interface with the customer's I/O. Due to the standardization of PCBs, the designer must attempt to optimize the area within the panel. Additionally, routing may be required, not only to give the PCB dimensional size, but also to disconnect from the panel. Thus, the use of PCB components can result in a number of problems in component assembly and manufacturing, which may not in fact be superior the use of lead frames.

In creating small electronic components, such as sensor devices, for example, packing designs utilize metal conductors and/or leadframes to connect such devices to an input component, which is typically not cost-effective with respect to the overall assembly and manufacturing process. The solution to such cost issues touches many elements of the resulting component structure, such as material, labor and capital. A need thus exists for an assembly process, which overcomes these cost issues, while also providing the full capabilities of devices, such as PCB, leadframe and/or metal conductor components. It is believed that a solution to these problems lies in the combined use of Filp Chip and conductive plastic trace assembly techniques, which are disclosed in greater detail herein.

### BRIEF SUMMARY OF THE INVENTION

The following summary of the invention is provided to facilitate an understanding of some of the innovative features unique to the present invention and is not intended to be a full description. A full appreciation of the various aspects of the invention can be gained by taking the entire specification, claims, drawings, and abstract as a whole.

It is, therefore, one aspect of the present invention to provide an improved packaging assembly method and system.

It is another aspect of the present invention to provide for a packaging assembly which can be produced utilizing flip chip and conductive plastic trace techniques in order to enhance package manufacturing processes.

The aforementioned aspects of the invention and other objectives and advantages can now be achieved as described herein. Packaging assembly methods and systems are disclosed herein. Initially, a plastic substrate can be provided. Thereafter, the plastic substrate can be configured as a conductive plastic trace assembly. A die can then be connected to the conductive plastic trace assembly so that the conductive plastic trace assembly functions as a combined printed circuit board and package structure including electronic circuitry. The die can be connected to the conductive plastic trace assembly utilizing a conductive adhesive. Alternatively, the die can be connected to the conductive plastic trace assembly by solder, ultrasonic bonding, and/or gold-to-gold bonding. The die can be connected to the conductive plastic trace assembly utilizing flip chip techniques.

The plastic substrate itself can be configured to comprise a customer interface component for interfacing to other packaging components. The customer interface can include a plurality of tooling points, which match customer-specified requirements. Additional packaging components can be connected to said plastic substrate following the connection (e.g., soldering or conductive adhesive) of the conductive plastic trace assembly, thereby configuring said conductive plastic trace assembly to function as a combined printed circuit board and package structure that includes electronic circuitry thereon.

The entire unit (i.e., plastic substrate, conductive plastic trace assembly, die and said additional packaging components) can then be environmentally sealed to form the final packaging assembly. The packaging assembly can then be tested to ensure that said packaging assembly functions properly as a unit. The final unit itself can function as a sensor device.

### BRIEF DESCRIPTION OF THE DRAWINGS

The accompanying figures, in which like reference numerals refer to identical or functionally-similar elements throughout the separate views and which are incorporated in and form a part of the specification, further illustrate the present invention and, together with the detailed description of the invention, serve to explain the principles of the present invention.

FIG. 1 illustrates an exploded view of a packaging assembly, which can be manufactured in accordance with a preferred embodiment of the present invention; and

FIG. 2 illustrates a section of the packaging assembly depicted in FIG. 1 as assembled, in accordance with a preferred embodiment of the present invention.

### DETAILED DESCRIPTION OF THE INVENTION

The particular values and configurations discussed in these non-limiting examples can be varied and are cited merely to illustrate at least one embodiment of the present invention and are not intended to limit the scope of the invention.

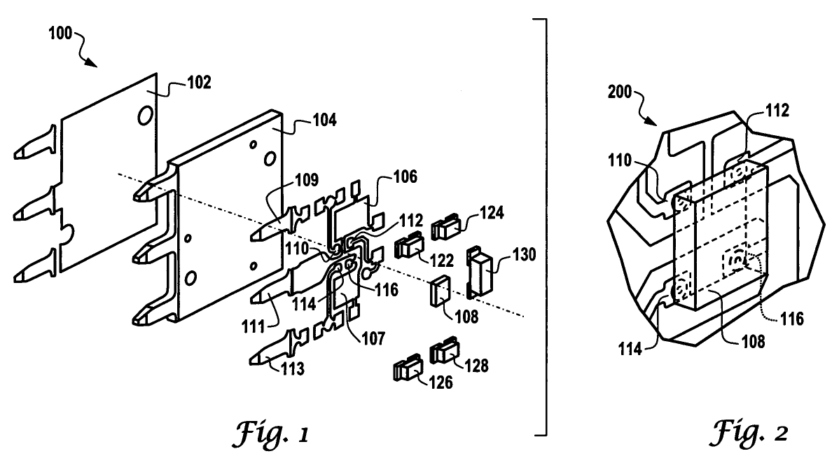

FIG. 1 illustrates an exploded view of a packaging system or packaging assembly 100, which can be manufactured in accordance with a preferred embodiment of the present invention. FIG. 2 illustrates a section 200 of the packaging assembly 100 depicted in FIG. 1 as assembled, in accordance with a preferred embodiment of the present invention. Note that in FIGS. 1 and 2, identical or similar parts or elements are indicated by identical reference numerals. A plastic substrate 104 can initially be provided, which is located between a bottom portion 102 and top portions 106, 107, 109, 111, and 113. Plastic substrate 104 can function as a plastic insulator. Bottom portion 102 can be configured from any conductive metal, for example, copper, nickel, and so forth. In the configuration of FIG. 1, bottom portion 102 can also be designed to function as an EMC shield.

The plastic substrate 104 can function as part of a conductive plastic trace assembly (i.e., packaging assembly 100) by connecting a die 108 to the plastic substrate 104 to thereby configure the resulting conductive plastic trace assembly to function as a combined printed circuit board and package structure that includes electronic circuitry thereon. Additional discrete components 122, 124, 126, 128, and 130 can also be connected to the plastic substrate 104 to create the conductive plastic trace assembly (i.e., packaging assembly 100). Discrete components 122, 124, 126, 128 and 130 can be implemented as conductive components, depending upon design considerations. Such a packaging assembly 100 additionally can include a plurality of conductive contacts 110, 112, 114, and 116 to which die 108 attaches.

In essence, two technologies can be combined to create a unique product or packaging assembly 100 depicted in FIG. 1. The two technologies are flip chip and conductive plastic traces. One example of a “flip chip” technique is Flip Chip On Board (FCOB), which can be implemented utilizing solder, ultrasonic bonding, gold-to-gold bonding, and/or a conductive adhesive (e.g., AiT) in order to attach the die 108 to plastic substrate 104. By utilizing conductive plastic trace technology, the plastic substrate becomes not only the “circuit board” but also functions as the package structure, customer interface, and interface to additional packaging components by creating tooling points for all of the listed or customer required items.

Such a packaging assembly 100 can create new manufacturing opportunities by increasing speed and reducing capital expenses due to the incorporation of tooling points into the plastic. The use of such tooling points promotes the consistent and accurate manipulation, placement, and structuring of packaging assemblies. As a result, few components are involved. There is not a need for a PCB, leadframe, or processes required for connecting such items. In addition, handling and joint inspection is eliminated.

The plastic trace becomes the PCB, packaging structure and electronic circuitry. This element can be constructed via processes such as Molded Interconnected Device (MID), EXACT, and vacuum metalizing. The MID method, for example, creates a conductor and an insulator by utilizing two different plastics in which one can be plated, while the second plastic (i.e., the insulator) can be molded over the plateable plastic, creating a pattern for the circuitry. In general, it is not important how the component is created. Rather, the fact that the plastic substrate 104 incorporates key elements for creating the packaging assembly 100 is important, including the structure, electronic circuitry and the metallization required for conduction and component interface.

There currently exists a requirement for noble metals to connect the flip chip to a substrate, such as plastic substrate 104, utilizing the method in which a conductive adhesive is utilized. An example of such a conductive adhesive is AiT, and construction techniques thereof are often referred to as the “AiT method”. Note that “AiT” generally refers to “AI Technology, which involves epoxy paste and film adhesive technology for electronics packaging. If other technologies are created in the future to permit an electrical interface using the plastic substrate 104 and the die 108, the methods and systems disclosed herein will still remain applicable.

The embodiments and examples set forth herein are presented to best explain the present invention and its practical application and to thereby enable those skilled in the art to make and utilize the invention. Those skilled in the art, however, will recognize that the foregoing description and examples have been presented for the purpose of illustration and example only. Other variations and modifications of the present invention will be apparent to those of skill in the art, and it is the intent of the appended claims that such variations and modifications be covered.

The description as set forth is not intended to be exhaustive or to limit the scope of the invention. Many modifications and variations are possible in light of the above teaching without departing from the scope of the following claims. It is contemplated that the use of the present invention can involve components having different characteristics. It is intended that the scope of the present invention be defined by the claims appended hereto, giving full cognizance to equivalents in all respects.

1. A packaging assembly method, comprising the steps of:
providing a plastic substrate; and
connecting at least one die and a plurality of conductive components to said plastic substrate to configure a conductive plastic trace assembly that functions as a combined printed circuit board and package structure that includes electronic circuitry thereon.

2. The method of claim 1 wherein the step of connecting said at least one die to said plastic substrate further comprises the step of:
connecting said at least one die to said plastic substrate utilizing a conductive adhesive.

3. The method of claim 2 wherein said plurality of conductive components comprises discrete components.

4. The method of claim 1 wherein the step of connecting said at least one die to said plastic substrate further comprises the step of:
connecting said at least one die to said plastic substrate by gold-to-gold bonding.

5. The method of claim 1 wherein the step of connecting said at least one die to said plastic substrate further comprises the step of:
connecting said at least one die to said plastic substrate utilizing FCOB.

6. The method of claim 1 further comprising the steps of:
connecting additional packaging components to said plastic substrate following connecting said at least one die to said plastic substrate; and
environmentally sealing said plastic substrate, said conductive plastic trace assembly, said die and said additional packaging components to form a packaging assembly.

7. The method of claim 6 further comprising the step of:
testing said packaging assembly to ensure that said packaging assembly functions properly as a unit.

8. The method of claim 6 wherein said packaging assembly comprises a sensor device.

9. The method of claim 1 further comprising the step of configuring said conductive plastic trace assembly to comprise a customer interface component for interfacing to other packaging components.

10. The method of claim 9 further comprising the step of configuring said customer interface to include a plurality of tooling points, which match customer-specified requirements.

11. A packaging assembly system, comprising:
a plastic substrate;
a die connected to said plastic substrate to configure a conductive plastic trace assembly therefrom, which functions as a combined printed circuit board and package structure that includes electronic circuitry thereon.

12. The system of claim 11 further comprising a conductive adhesive for connecting said die to said conductive plastic trace assembly.

13. The system of claim 12 wherein said plurality of conductive components comprises discrete components.

14. The system of claim 11 wherein said die is connected to said conductive plastic trace assembly by gold-to-gold bonding.

15. The system of claim 11 wherein said die is connected to said conductive plastic trace assembly by FCOB.

16. The system of claim 11 further comprising:
additional packaging components connected to said plastic substrate following connecting a die to said conductive plastic trace assembly to thereby configure said conductive plastic trace assembly to function as a combined printed circuit board and package structure that includes electronic circuitry thereon; and
a sealing component for environmentally sealing said plastic substrate, said conductive plastic trace assembly, said die and said additional packaging components to form a packaging assembly.

17. The system of claim 16 wherein said packaging assembly comprises a sensor device.

18. The system of claim 11 further comprising a customer interface component configured upon said conductive plastic trace assembly for interfacing to other packaging components.

19. The system of claim 18 wherein said customer interface comprises a plurality of tooling points, which match customer-specified requirements.

20. A packaging assembly system, comprising:
a plastic substrate;
a conductive plastic trace assembly configured upon said plastic substrate;
a die connected to said conductive plastic trace assembly so that said conductive plastic trace assembly functions as a combined printed circuit board and package structure that includes electronic circuitry thereon;
a conductive adhesive for connecting said die to said conductive plastic trace assembly; and
a customer interface component configured upon said conductive plastic trace assembly for interfacing to other packaging components, wherein said customer interface comprises a plurality of tooling points, which match customer-specified requirements.
